(19) United States
(12) Patent Application Publication
(10) Pub. No.: US 2010/0255424 A1
(43) Pub. Date: Oct. 7, 2010

(54) LIQUID DISCHARGE HEAD MANUFACTURING METHOD

(75) Inventors: Shoji Shiba, Yokohama-shi (JP); Kazunari Ishizuka, Suntou-gun (JP); Yasuaki Tominaga, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/681,227

(22) PCT Filed: Dec. 18, 2008
(86) PCT No.: PCT/JP2008/073673

§ 371 Date: Apr. 1, 2010

(30) Foreign Application Priority Data
Dec. 19, 2007 (JP) 2007-327473
Oct. 29, 2008 (JP) 2008-278427

(51) Int. Cl. G03F 7/20

(52) U.S. Cl. 430/319

(57) ABSTRACT

Provided is a method for manufacturing a liquid discharge head including a flow path forming member connected to a discharge port on or above a substrate, the method including: providing a layer containing a photosensitive resin on or above the substrate; providing a mask layer that enables reduction of transmission of light with a photosensitive wavelength of the photosensitive resin, at an area on the layer containing the photosensitive resin, the area corresponding to the flow path; performing exposure for the layer containing the photosensitive resin using the mask layer to make the layer containing the photosensitive resin be a pattern having the shape of the flow path; providing a layer that becomes the flow path forming member, so as to cover the pattern; forming the discharge port at a part of the layer that becomes the flow path forming member; and forming the flow path by removing the pattern.

### TECHNICAL FIELD

The present invention relates to a method for manufacturing a liquid discharge head that discharges a liquid, and specifically relates to a method for manufacturing an ink jet recording head that performs recording by discharging an ink onto a recording medium.

### BACKGROUND ART

Examples of use of a liquid discharge head that discharges a liquid include an ink jet recording method in which recording is performed by discharging an ink onto a recording medium.

In general, an ink jet recording head employed for an ink jet recording method (liquid jet recording method) includes an ink flow path, discharge energy generating units provided at a part of the flow path, and fine ink discharge ports (called “orifices”) for discharging an ink by means of energy generated in the discharge energy generating units. Examples of a method for manufacturing such ink jet head include the method disclosed in U.S. Pat. No. 4,657,631. In this method, a patterned layer, which is a template for a flow path, is formed on a substrate having discharge energy generating elements using a photosensitive material, and a flow path wall forming member is provided on the patterned layer, and subsequently, the patterned layer is removed, thereby forming a space for an ink flow path. This method is an application of a photolithographic technique for semiconductor, and enables highly-precise fine processing for forming an ink flow path, discharge ports, etc.

A positive photosensitive resin is used for the pattern, which is a template for the aforementioned flow path, and a photolithographic technique is used for patterning the positive photosensitive resin. For an exposure apparatus for exposing such positive photosensitive resin to light, an exposure apparatus of the type in which the entire substrate is exposed to light at one time with a magnification of 1 to 1 is used in connection with a required exposure amount. When exposure is performed using an exposure apparatus of the type in which deep-UV light (with a wavelength of no more than 300 nm), which is a photosensitive wavelength of the positive photosensitive resin, is applied at one time, the following cases can be contemplated.

First, since the entire target object (positive photosensitive resin) with a large area provided on the substrate is exposed to light at one time, the accuracy of alignment between the object and a mask used for exposure is insufficient. Particularly, when a target object is exposed to light on a large-size wafer of around 8 to 12 inches, the accuracy of alignment between the mask and the target object may vary within the same substrate, and depending on the substrate subjected to exposure, due to the effect of, e.g., warpage of the substrate and/or deflection of the mask.

Also, as the positive photosensitive resin, in general, main chain decomposition-type positive photosensitive resin is used, many of the main chain decomposition-type positive photosensitive resin have a low sensitivity to ultraviolet light, and thus, it is necessary to apply a large amount of energy to cause a sufficient decomposition reaction. Accordingly, non-uniform thermal expansion may occur in the mask and the substrate because of heat generation during exposure, resulting in deterioration of the resolution and the alignment accuracy.

For example, in a method for manufacturing an ink jet recording head such as one disclosed in, for example, U.S. Pat. No. 4,657,631, in general, exposures of a positive photosensitive resin layer, which forms a flow path pattern, and a coating resin layer are performed with reference to alignment marks formed on the substrate. If there are no misalignments, as illustrated in FIG. 14A, a desired mutual positional relationship can be provided among energy generating elements 20, a flow path-shaped pattern 30, and discharge ports 50. Meanwhile, if variation occurs in alignment accuracy as mentioned above, as illustrated in FIG. 14B, the mutual positional relationship among the energy generating elements 20, the flow path-shaped pattern 30, and the discharge ports 50 may differ from a desired one. In that case, in a manufactured head, a desired resistance of a fluid in the flow path to the energy generating elements and the discharge ports may not be provided. According to the above, occurrence of variation in alignment as mentioned above may affect the discharge performance of the manufactured ink jet recording head.

### DISCLOSURE OF THE INVENTION

The present invention has been made in view of the aforementioned problems, and an object of the present invention is to provide a method for stably manufacturing an ink jet head with favorable printing properties, in which the positional relationship among discharge energy generating elements, an ink flow path and discharge ports can be controlled with high accuracy and good reproducibility.

The present invention provides a method for manufacturing a liquid discharge head including a flow path forming member for forming a flow path communicably connected to a discharge port that discharges a liquid on or above a substrate, the method comprising: providing a layer containing a photosensitive resin on or above the substrate; providing a mask layer that enables reduction of transmission of light with a photosensitive wavelength of the photosensitive resin, at an area on the layer containing the photosensitive resin, the area corresponding to the flow path; performing exposure for the layer containing the photosensitive resin using the mask layer as a mask to make the layer containing the photosensitive resin be a pattern having the shape of the flow path; providing a layer that becomes the flow path forming member, so as to cover the pattern; forming the discharge port at a part of the layer that becomes the flow path forming member; and forming the flow path by removing the pattern.

The present invention enables stable manufacture of an ink jet head with favorable printing properties, in which the positional relationship among discharge energy generating elements, an ink flow path and discharge ports can be controlled with high accuracy and good reproducibility.

Further features of the present invention will become apparent from the following description of exemplary embodiments with reference to the attached drawings.

### BRIEF DESCRIPTION OF THE DRAWINGS

FIG. 1 is a schematic perspective view illustrating an example of an ink jet head according to the present invention.

FIGS. 2A, 2B, 2C, 2D and 2E are schematic cross-sectional views illustrating an example of an ink jet head manufacturing method according to the present invention.

FIGS. 3A, 3B, 3C and 3D are schematic cross-sectional views illustrating an example of an ink jet head manufacturing method according to the present invention.

FIGS. 4A, 4B, 4C and 4D are schematic cross-sectional views illustrating an example of an ink jet head manufacturing method according to the present invention.

FIGS. 5A, 5B, 5C and 5D are schematic cross-sectional views illustrating an example of an ink jet head manufacturing method according to the present invention.

FIGS. 6A and 6B are schematic cross-sectional views illustrating an example of an ink jet head manufacturing method according to the present invention.

FIG. 7 is a diagram illustrating absorption spectra of a positive photosensitive resin and a resist used for a mask, which are used in an example of the present invention.

FIG. 8 is a diagram illustrating the relationship between wavelength and luminance of light, which is used in an example of the present invention.

FIG. 9 is a diagram illustrating absorbance spectra of a positive photosensitive resin and a resist used for a mask, which are used in an example of the present invention.

FIGS. 10A and 10B are schematic views for describing an evaluation method.

FIGS. 11A, 11B and 11C are schematic views for describing an evaluation method.

FIGS. 12A, 12B, 12C, 12D, 12E, 12F, 12G and 12H are schematic cross-sectional views illustrating an example of an ink jet head manufacturing method according to the present invention.

FIGS. 13A, 13B and 13C are schematic cross-sectional views illustrating an example of an ink jet head manufacturing method according to the present invention.

FIGS. 14A and 14B are diagrams used for describing related art and problems to be solved.

FIGS. 15A, 15B, 15C and 15D are schematic cross-sectional views illustrating an example of an ink jet head manufacturing method according to the present invention.

FIGS. 16A, 16B, 16C, 16D, 16E, 16F, 16G and 16H are schematic cross-sectional views illustrating an example of an ink jet head manufacturing method according to the present invention.

FIG. 17 is a schematic view for describing an evaluation method.

FIGS. 18A, 18B, 18C and 18D are schematic cross-sectional views illustrating a comparative example.

### BEST MODES FOR CARRYING OUT THE INVENTION

Embodiments of the present invention will be described with reference to the drawings. In the below description, components with the same function are provided with the same reference numeral in the drawings, and the description thereof may not be repeated.

Also, the below description is provided in terms of an ink jet head as an example of liquid discharge heads. A liquid discharge head can be applied in industrial fields such as color filter manufacturing.

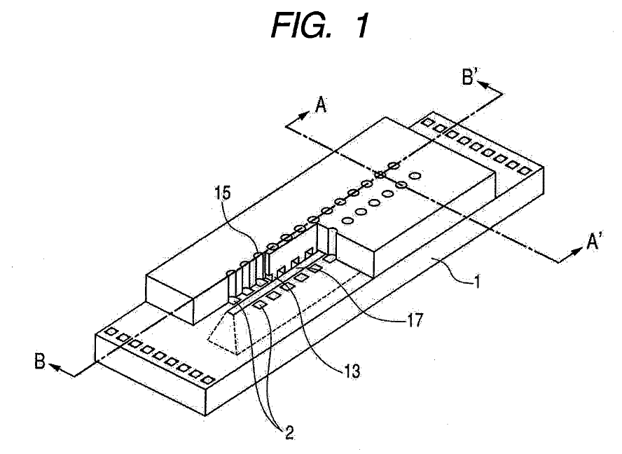

FIG. 1 is a schematic partial cross-sectional perspective view illustrating an example of the structure of an ink jet head, which is an example of the present invention. This ink jet head includes a plurality of discharge ports 15 for discharging an ink; and an ink flow path 17 communicably connected to the discharge ports and including discharge energy generating elements 2 for discharging an ink, in its inside. Here, “including discharge energy generating elements 2 in its inside” means that the discharge energy generating elements 2 are provided at predetermined positions inside the ink flow path 17. Also, the ink flow path 17 has an ink flow path forming member 13 formed on a substrate 1 on which the plurality of discharge energy generating elements 2 is formed. In the present embodiment, the discharge ports 15 are provided in the ink flow path forming member 13 in such a manner that the discharge ports 15 form openings.

### First Embodiment

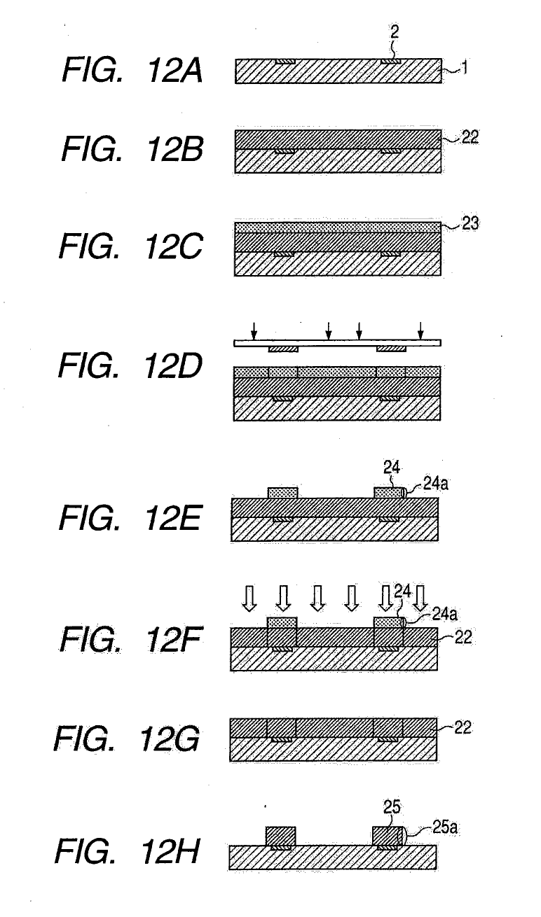

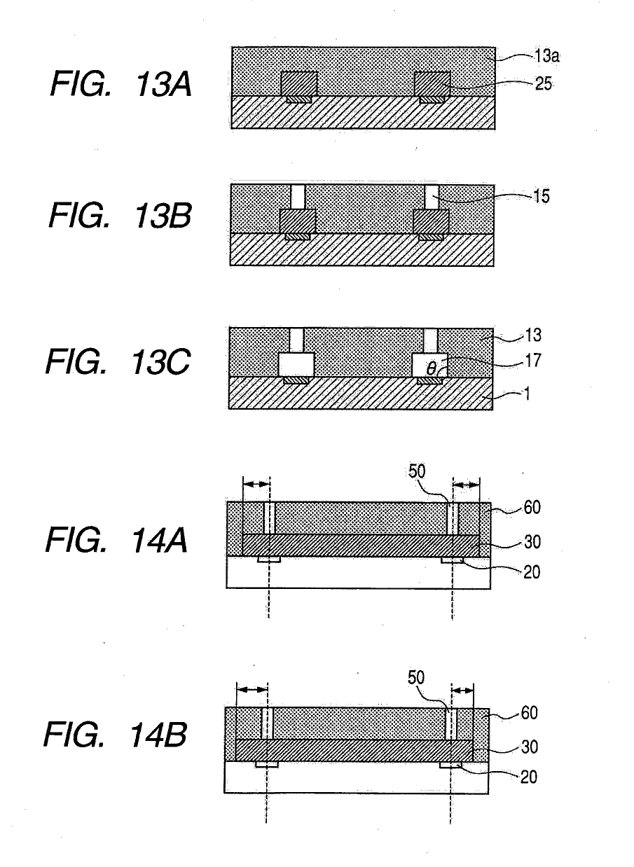

FIGS. 12A to 12H and FIGS. 13A to 13C are diagrams illustrating an example of an ink jet head manufacturing method according to the present invention. These figures correspond to schematic cross-sectional views of the ink jet head in FIG. 1 taken along line B-B′.

First, as illustrated in FIG. 12A, a substrate 1 including energy generating elements 2 that generate energy used for discharging a liquid is provided. Examples of the energy generating elements 2 include heaters and piezoelectric elements. For the substrate 1, silicon is used. For enhancement of durability of the energy generating elements 2, various kinds of functional layers, such as a protective layer (not illustrated), can be provided. For example, a film of SiN, SiC and/or Ta may be provided on a surface of the substrate.

Next, as illustrated in FIG. 12B, a first layer 22, containing a positive photosensitive resin, for forming a pattern having the shape of a flow path is formed on the substrate. Examples of the positive photosensitive resin include main chain decomposition-type positive photosensitive resins such as polymethyl isopropenyl ketone and polyvinyl ketone. The examples can also include polymeric main chain decomposition-type positive photosensitive resins containing ester methacrylate as a main component, for example, homopolymers such as polymethyl methacrylate and polyethyl methacrylate, and copolymers of methyl methacrylate, and, e.g., a methacrylic acid, an acrylic acid, glycidyl methacrylate or phenyl methacrylate. Also, negative photosensitive resins can be used.

Next, as illustrated in FIG. 12C, a second layer 23, containing a photosensitive resin composition, which becomes a mask for patterning the first layer 22, is provided on the first layer 22. This photosensitive resin composition can be patterned by means of a stepper from the perspective of alignment accuracy, using an i-ray (365 nm), which is most widely used. More specifically, exposure can be performed using a reduced projection exposure apparatus that provide an i-ray. Particularly, a positive photoresist containing a novolac resin and a naphthoquinone diazide derivative can be used. As an example, a naphthoquinone-type positive photoresist such as an OFPR-800 resist or an iP-5700 resist (product names), which are marketed by Tokyo Ohka Kogyo Co., Ltd., can be used.

The second layer 23 containing the photosensitive resin composition can further contain a hydroxybenzophenone compound. When an alkaline developer is used for patterning a naphthoquinone-type positive photoresist, a diazotization reaction occurs at the surface part of the naphthoquinone diazide-type resist, resulting in the phenomenon that solubility of, the naphthoquinone diazide-type resist in the developer is lowered being observed. Meanwhile, at the lower part of the resin layer, which is not in contact with alkaline, the solubility does not change. Thus, it can be contemplated that control of the pattern edge shape of the resist mask becomes difficult because the development speed is different between the surface part and the lower part.

In the case where the second layer 23 contains a hydroxybenzophenone compound, the solubility of the second layer 23 in alkaline is raised by the effect of an OH group contained in the hydroxybenzophenone compound. Thus, at the time of development for patterning the second layer 23, which will be described later, the development speed of the exposed part is enhanced. Consequently, even when a diazotization reaction occurs at the surface part of the second layer 23 under an alkaline environment, it is possible to prevent the surface part from having the tendency of becoming insoluble in the developer, thereby enabling the surface and the lower part to have the same development speed, and thus, development can be performed so as to provide perpendicular edges.

Also, the present inventors have discovered that the aforementioned development speed varies depending on the number of OH groups in the hydroxybenzophenone compound. In particular, hydroxybenzophenone with one OH group, the surface part and the lower part are substantially equal to each other in terms of development speed in development using an alkali solution, enabling obtainment of edges 24a in a resist mask 24 in shapes close to perpendicular shapes. Furthermore, if the hydroxybenzophenone compound has a hydrophobic group such as a long-chain alkoxy group, the alkali development speeds of the upper layer and the lower layer can be made to be the same, which is preferable because a perpendicular patterning shape can be obtained.

Examples of the hydroxybenzophenone compound include 2-hydroxy-4-octoxybenzophenone, 2-hydroxy-4-methoxybenzophenone, and 2,4-dihydroxybenzophenone. The examples can also include 2,3,4-trihydroxybenzophenone, 2,3,4,4′-tetrahydroxybenzophenone and 2,3′,4,4′-tetrahydroxybenzophenone.

No less than 5 weight parts and less than 12 weight parts of a hydroxybenzophenone compound can be provided in 100 weight parts of solid contents contained positive photoresist.

Furthermore a hydroxybenzophenone compound can be provided from the perspective of its ability to enhance the light blocking effect of the second layer 23. The second layer 23 on the first layer 22 is used as a mask when the first layer 22 is patterned by means of photolithography, and accordingly, the second layer 23 is required to have a light blocking effect. By the effect of an aromatic ring included in the hydroxybenzophenone compound, the light blocking effect for blocking light with a wavelength for exposure of the positive photosensitive resin contained in the first layer 22 can be enhanced. Consequently, the light blocking effect can be enhanced without increasing the thickness of the second layer 23.

If the second layer 23 is provided on the first layer 22 by means of coating, it is preferable to make consideration to prevent the first layer 22 from dissolving.

Next, as illustrated in FIG. 12D, the second layer 23 is exposed to light using a mask.

Next, as illustrated in FIG. 12E, development is performed to form a resist pattern 24 corresponding to the shape of a flow path. At this time, by the aforementioned effect of the hydroxybenzophenone compound, the edge portions 24a have shapes substantially perpendicular to the surface of the first layer 22.

Next, as illustrated in FIG. 12F, the first layer 22 is exposed to light using the resist pattern 24 as a mask. Light used for exposure at this time is blocked by the resist pattern 24. The light blocking at this time refers to, e.g., absorbing or reflecting light so that the light does not penetrate the first layer 22. This means not only completely eliminating light going toward the first layer 22, but also blocking the light to the extent required for obtaining a favorable pattern for the first layer 22.

Next, as illustrated in FIG. 12G, the resist pattern 24, which has been used as a mask, is removed. The removal of the resist pattern 24 is performed using a solvent. Here, in general, a naphthoquinone-type positive photoresist functions as a positive resist in a proper exposure amount, and the exposed portions easily dissolve in an alkaline aqueous solution. However, when a large exposure amount is applied, a cross-linking reaction occurs between molecules of the resin that is a main component, and accordingly, the naphthoquinone-type positive photoresist may be hard to dissolve in an alkaline aqueous solution or a common organic solvent. When the first layer 22 is a thick film, application of a large amount of energy is required. Thus, a large amount of energy is applied also onto the resist pattern 24, causing the cross-linking reaction to progress, which may result in difficulty to remove the resist pattern 24.

Therefore, a mixed solution of a glycol ether with a carbon number of 6 or more and a nitrogenous basic organic solvent, which can be mixed with water at an arbitrary ratio, and water is effective for removal of the naphthoquinone-type photoresist in which a cross-linking reaction has occurred. Since the mixed solvent has both a dissolving ability as an organic solvent, and a dissolving ability as an alkaline aqueous solution, it can be presumed to have properties favorable for dissolving the naphthoquinone-type photoresist in which a cross-linking reaction has occurred.

Next, as illustrated in FIG. 12H, development is performed for the first layer 22, obtaining a pattern 25 (flow path pattern 25) having the shape of the flow path of the ink jet head. Since the edge shapes 24a of the resist pattern 24, which is a mask, exhibit a high perpendicularity, the shapes of edge portions 25a of the pattern 25 also exhibit a high perpendicularity to the substrate. The shape of the pattern 25 is transferred to the shapes of the walls of a flow path 17, which will be described later. Thus, if the edge portions 25a of the pattern 25 can be formed in shapes close to be perpendicular to the substrate, the angle θ between the wall portions of the flow path 17 formed by a flow path forming member 13 in FIG. 13C and the substrate 1 can be made to be close to 90°. When the angle θ is close to 90°, if the area of contact between the substrate 1 and the flow path forming member 13 does not change, the volume of the flow path 17 becomes large, enabling reduction of flow resistance in the flow path 17, which is favorable because the filling speed of the liquid to be discharge is enhanced. When a negative photosensitive resin is used for the first layer 22, the portions subjected to exposure are cured, and thus, the portions below the mask 24 are removed by development.

Next, as illustrated in FIG. 13A, a coating layer 13a, which becomes the flow path forming member 13, is provided on the pattern layer so that the coating layer 13a covers the flow path pattern 25. A material with a film thickness of 20 μm is formed by means of a coating method such as ordinary spin coating, roll coating or slit coating. Here, in forming the coating layer 13a, which becomes the flow path forming member 13, the coating layer 13a needs to have properties, such as those not deforming the flow path pattern 25. In other words, when a coating layer is deposited on the flow path pattern 25 by means of, e.g., spin coating or roll coating, it is necessary to select a solvent so as to avoid the soluble flow path pattern 25 from dissolving. Also, the material for forming the flow path forming member 13 can be a photosensitive material because a photosensitive material can form discharge ports 15 for an ink, which will be described later, easily with high accuracy by means of photolithography. For the material of the resin coating layer 13a, a high mechanical strength as a structural material, adherence to the underlying material, ink tolerance, and a resolution for patterning a fine pattern of ink discharge ports are required. For a material satisfying these properties, a cationic polymerization-type epoxy resin composition can be employed.

Examples of an epoxy resin used for the present invention can include a reactant between bisphenol A and epichlorohydrin with a molecular weight of around 900 or more from among reactants between bisphenol A and epichlorohydrin, and a reactant between bromine-containing bisphenol A and epichlorohydrin. The examples can also include a reactant between phenol novolac or o-cresol novolac and epichlorohydrin, and a polyfunctional epoxy resin including an oxycyclohexane skeleton, which is disclosed in Japanese Patent Application Laid-Open No. H02-140219, but are not limited to these compounds.

For the aforementioned epoxy compound, preferably, a compound with an epoxy equivalent of 2000 or less, and more preferably, a compound with an epoxy equivalent of 1000 or less is used.

For a photocationic polymerization initiator for curing the aforementioned epoxy resin, a compound that generates an acid upon application of light, and, for example, SP-150, SP-170 and SP-172, which are marketed by Adeka Corporation, are suitable for use.

Furthermore, an additive or the like can arbitrarily be added in the aforementioned composition as necessary. For example, a flexibilizer can be added to lower the degree of elasticity of the epoxy resin, or a silane coupling agent can be added to obtain further adhesiveness to the underlying material.

Next, pattered exposure is performed for the coating resin layer 13a via a mask (not illustrated) and development processing is performed, thereby forming discharge ports 15 at positions facing the energy generating elements. Next, the ink flow path forming member 13 subjected to the patterned exposure is developed using a proper solvent, thereby forming the discharge ports 15, entering the state illustrated in FIG. 13B.

As illustrated in FIG. 13C, after a liquid supply port (not illustrated) communicably connected to the flow path 17 is formed on the substrate, the pattern 25 is removed, thereby obtaining the flow path 17 and the flow path forming member 13.

Next, after performing a step of separation by cutting (not illustrated), the flow path pattern 25 is removed by being dissolved. Furthermore, after the ink flow path forming member 13 is further cured by performing heating processing as necessary, connection to a member for ink supply (not illustrated) and electrical connection to drive the energy generating elements (not illustrated) is provided, enabling obtainment of an ink jet head.

### Second Embodiment

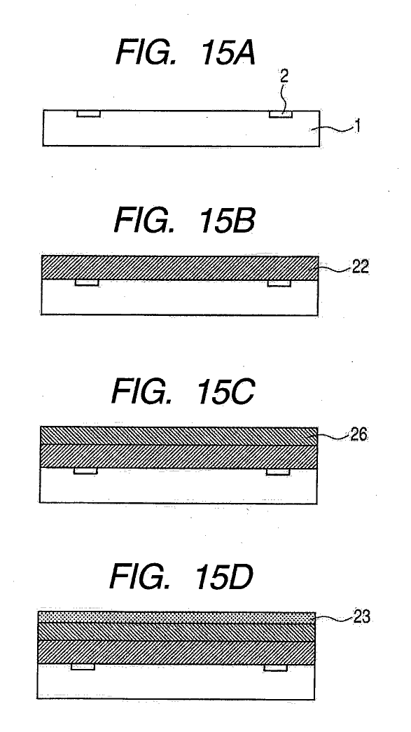

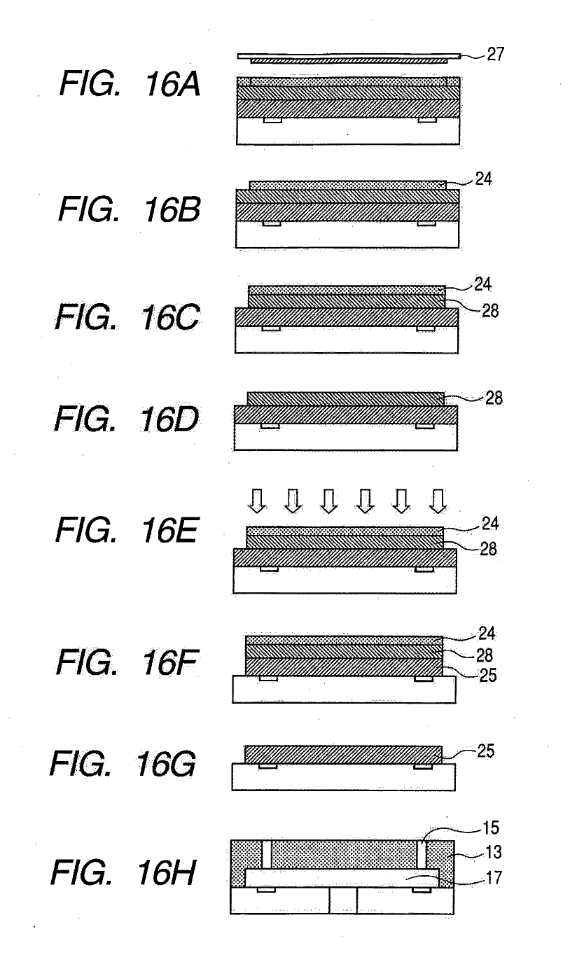

Next, a second embodiment of the present invention will be described with reference to FIGS. 15A to 15D and FIGS. 16A to 16H, which are schematic cross-sectional views taken along line A-A′ of the ink jet head in FIG. 1.

First, a substrate 1, such as one illustrated in, for example, FIG. 15A, is provided. For this substrate, although any substrate that can function as a part of an ink flow path forming member, and also function as a support for a material layer that forms an ink flow path and ink discharge ports, which will be described later, can be used with no specific limitations of its shape, material, etc., a silicon substrate is used in general.

Next, as illustrated in FIG. 15B, a first layer 22 containing a positive photosensitive resin is formed on a substrate 1. The first layer 22 containing a positive photosensitive resin can be provided according to a method similar to the method in embodiment 1.

Next, as illustrated in FIG. 15C, a resin composition layer 26 having a light blocking effect for light in the photosensitive wavelength range of the first layer 22 containing a positive photosensitive resin is formed on the first layer 22.

A resin composition here used for forming the resin composition layer 26 functions as a mask for patterning the first layer 22, which will be described later, and is required to be able to block light in the photosensitive wavelength range of the first layer 22. Furthermore, in the later-described process, the resin composition is required to be subjected to patterning by means of etching using the pattern of the second layer 23 as a mask. For the etching method, wet etching can be used: the composition resin can be dissolved in the developer for the second layer 23 or a solvent that does not dissolve the second layer 23.

For a resin composition satisfying these requirements, a mixture of a resin having coating ability and a light-blocking material can be used. For the resin having coating ability, a general-purpose resin like an acrylic polymer containing an acrylic monomer as a main component, such as an acrylic acid, methyl methacrylate, hydroxyethyl methacrylate or hydroxyphenyl methacrylate, a vinyl polymer such as polyvinyl alcohol, or a novolac polymer such as phenol novolac or cresol novolac, can be used.

For the light-blocking material, although the aforementioned resin can be used with a dye or pigment properly added thereto, it is necessary to select a material that can block light in the photosensitive wavelength range of the first positive resist. More specifically, examples of a light-blocking material that can provide a high light-blocking effect with a small amount include carbon black and titanium black. In particular, it is favorable to use carbon black, a known carbon black, such as channel black, furnace black, thermal black or lamp black, can be used. Also, for enhancing dispersibility in the aforementioned resin, resin-coated carbon black can be used.

For the resin composition having a light-blocking effect for light in the photosensitive wavelength range of the first layer 22 used for the present invention, for example, an alkali-soluble resin composition can be obtained by dispersing carbon black in cresol novolac.

Next, as illustrated in FIG. 15D, the second layer 23 is formed on the resin composition layer 26 having a light-blocking effect for the photosensitive wavelength range of the first positive resist.

For the second layer 23, although a negative or positive resist can be used, a resist that can be subjected to alkaline development is favorable for ease of handling. Furthermore, in the present invention, patterning can be performed by means of a stepper from the perspective of alignment accuracy, using an i-ray (365 nm), which is most widely used. A resist satisfying these requirements can be a positive photoresist containing a novolac resin and a naphthoquinone diazide derivative. As an example, a general-purpose naphthoquinone-type positive photoresist, such as OFPR-800 resist or iP-5700 resist (product names) marketed by Tokyo Ohka Kogyo Co., Ltd., can be used.

Next, as illustrated in FIG. 16A, patterned exposure is performed via a first reticle (mask) 27 and development processing is performed, thereby forming a resist pattern 24 corresponding to the shape of a flow path, entering the state illustrated in FIG. 16B.

At this time, if an alkali-soluble resin composition is used for the resin composition layer 26 and an alkaline development-type positive photoresist is used as the second layer 23, development of the resist and etching of the resin composition can simultaneously be performed. Then, as illustrated in FIG. 16C, the resist pattern 24 (upper layer) and another pattern 28 (lower layer) containing the resin composition having a light-blocking effect for the photosensitive wavelength range of the first layer 22 can be formed at one time.

If the resin composition having a light-blocking effect for the photosensitive wavelength range of the first layer 22 is insoluble in alkali, etching may be performed by means of a proper organic solvent using the resist pattern 24 formed of the second layer 23 as a mask after hard-baking the resist pattern 24. Also, the resin composition may be patterned by means of dry etching using the resist pattern 24 as a mask. The resist pattern 24 is not particularly required to be removed, but the resist pattern 24 can be removed to enter the state illustrated in FIG. 16D where required by the subsequent process.

Next, exposure of the entire surface is performed using light with a photosensitive wavelength of the first layer 22, using the resist pattern 24 and the other pattern 28 as masks (FIG. 16E), and development of the first layer 22 is performed, thereby forming a pattern 25 having the shape of an ink flow path (FIG. 16F). As described above, as a result of using the two layers 24 and 28 in the figures as masks when exposing the first layer 22 to light, the light-blocking effect for light used for exposure can further be enhanced. Also, patterning to obtain the other pattern 28 is performed using the resist mask 24, and thus, the other pattern 28 is formed with high positional accuracy.

Subsequently, the resist pattern 24 and the other pattern 28 used as masks are removed, thereby the pattern 25 having the shape of an ink flow path is completed (FIG. 16G).

It is also possible that: exposure of the entire surface is performed for the first layer 22 from the state illustrated in FIG. 16D; and removal of the other pattern 28 is performed simultaneously with the development of the first layer 22.

Using the pattern 25 of the flow path formed as described above, the method described in embodiment 1 with reference to FIGS. 13A to 13C are performed to form a flow path 17, discharge ports 15, a flow path forming member 13 as illustrated in FIG. 16H.

### Third Embodiment

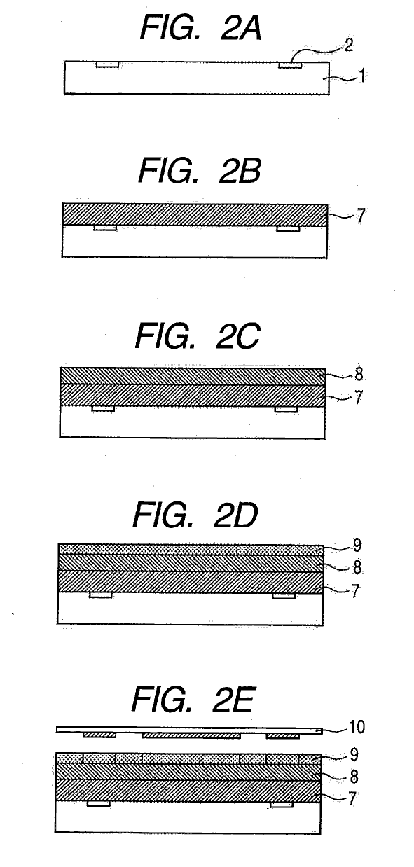

FIGS. 2A to 2E, FIGS. 3A to 3D, FIGS. 4A to 4D, FIGS. 5A to 5D and FIGS. 6A and 6B are diagrams illustrating an example of an ink jet head manufacturing method according to the present invention. These diagrams corresponding to schematic cross-sectional views of the ink jet head in FIG. 1 taken along line A-A′. Also, the method illustrated in FIGS. 2A to 2E, FIGS. 3A to 3D, FIGS. 4A to 4D, FIGS. 5A to 5D and FIGS. 6A and 6B is an example of forming an ink flow path, which has variation in height direction by means of a template pattern with a two-tier configuration in which the upper layer and the lower layer are different in shape from each other. Hereinafter, this type of ink flow path is referred to as “ink flow path with a two-tier configuration”.

First, as shown in FIG. 2A, a substrate 1 is provided as in the second embodiment.

Next, as shown in FIG. 2B, a first positive photosensitive resin layer 7 is formed on the substrate 1 on which energy generating elements 2 are formed. Then, as shown in FIG. 2C, a second positive photosensitive resin layer 8 is further deposited on the first positive photosensitive resin layer 7.

The first positive photosensitive resin and the second positive photosensitive resin need to be different from each other in photosensitive wavelength range. This is for, when patterning one positive photosensitive resin by means of exposure, preventing another positive photosensitive resin from being affected by the exposure. In the present invention, the photosensitive wavelength range of the first positive photosensitive resin is referred to as the “first wavelength range”. Also, the photosensitive wavelength range of the second positive photosensitive resin is referred to as the “second wavelength range”. The first wavelength range and the second wavelength range need to be different from each other.

Exemplary examples of the first and second positive photosensitive resins include a combination of a polymeric main chain decomposition-type positive photosensitive resin containing ester methacrylate as a main component and polymethyl isopropenyl ketone. In general, a polymeric main chain decomposition-type positive photosensitive resin containing ester methacrylate as a main component is sensitive to light in a wavelength range of around 200 to 240 nm. Meanwhile, polymethyl isopropenyl ketone is sensitive to light in a wavelength range of around 260 to 320 nm. In this combination, there is no specific limitation on the positional relationship of the upper and lower layers: there is no problem in which is used for the upper layer (second positive photosensitive resin layer 8) and which is used for the lower layer (first positive photosensitive resin layer 7).

The polymeric main chain decomposition-type positive photosensitive resin containing ester methacrylate as a main component may either a homopolymer or a copolymer. Specific examples of the homopolymer include polymethyl methacrylate and polyethyl methacrylate. Specific examples of the copolymer include a copolymer of methyl methacrylate and, e.g., a methacrylic acid, an acrylic acid, glycidyl methacrylate or phenyl methacrylate.

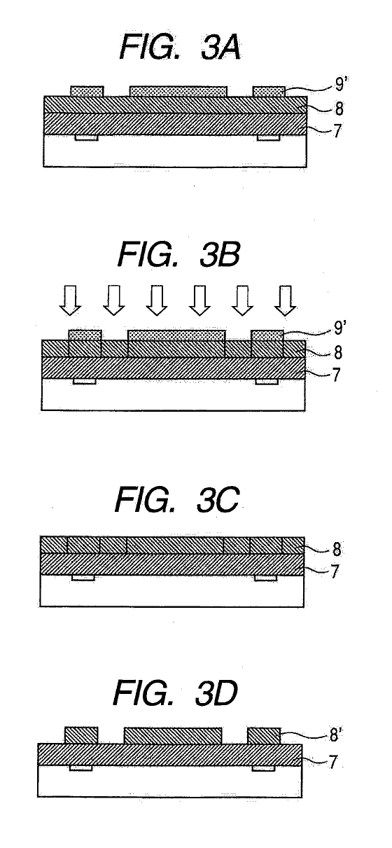

Next, as shown in FIG. 2D, a first resist 9 (first resist) is deposited on the second positive photosensitive resin layer 8. Then, as shown in FIG. 2E, patterned exposure is performed via a first reticle (mask) 10. Furthermore, as shown in FIG. 3A, development processing is performed, thereby forming a mask 9′ formed of the first resist on the second positive photosensitive resin layer 8.

The first resist 9 is provided to form a mask in an exposure process for patterning the second positive photosensitive resin layer 8 (FIG. 3B). Accordingly, the first resist 9 needs to have a light-blocking effect for light with the photosensitive wavelengths (the second wavelength range) of the second positive photosensitive resin. In the present invention, a mask formed by a resist may be referred to as a “mask resist”.

The first resist 9 can be patterned by means of a stepper from the perspective of alignment accuracy, using an i-ray (365 nm), which is used most widely. More specifically, exposure can be performed using a reduced projection exposure apparatus that provide an i-ray. Examples of a favorable positive resist satisfying these requirements include a positive photoresist containing a naphthoquinone diazide derivative, such as a positive photoresist containing a novolac resin and a naphthoquinone diazide derivative. Specific examples thereof include general-purpose naphthoquinone-type positive photoresists such as an OFPR-800 resist (product name) and an iP-5700 resist (product name) marketed by Tokyo Ohka Kogyo Co., Ltd.

Next, as shown in FIG. 3B, exposure of the entire surface is performed using light with a photosensitive wavelength of the second positive photosensitive resin layer 8 via the mask 9′ formed of the first resist. In this exposure, light in a wavelength range to which the first positive photosensitive resin layer 7 is not sensitive but the second positive photosensitive resin layer 8 is sensitive selectively applied. Then, as shown in FIG. 3C, the mask 9′ formed of the first resist is removed. Furthermore, as shown in FIG. 3D, development of the second positive photosensitive resin layer 8 is performed, thereby forming the upper layer 8′, which is a template pattern that is a part of a template pattern for an ink flow path. Also, the removal of the mask 9′ in FIG. 3C and the development processing for the second positive photosensitive resin layer 8 in FIG. 3D can be performed simultaneously using the same solvent. Also, the development processing for the second positive photosensitive resin layer 8 in FIG. 3D can be performed before the removal of the mask 9′ in FIG. 3C.

FIG. 7 is a graph illustrating an example of the photosensitive wavelengths of the resin forming the second positive photosensitive resin layer 8 and the light-blocking effect of the first resist 9. Here, a copolymer of methyl methacrylate and a methacrylic acid (relative proportion of monomers=90:10) was used as the second positive photosensitive resin layer 8, and a product named iP-5700 resist manufactured by Tokyo Ohka Kogyo Co., Ltd was used as the first resist 9. D in the figure indicates the absorption spectrum of the positive photosensitive resin layer 8, E indicates the absorption spectrum of the mask 9′ in the state shown in FIG. 3A, and F indicates the absorption spectrum of the mask 9′ after the process in FIG. 3B. It can be seen from FIG. 7 that: the photosensitive wavelengths of the copolymer are mainly 250 nm or less (data for a film thickness of 5 μm); and light with the photosensitive wavelengths of the copolymer can be blocked by using the iP-5700 resist (data for a film thickness of 4 μm). Also, although it is known that a naphthoquinone-type positive photoresist, upon exposure, fades and becomes transparent, it can be seen in this example that a sufficient light-blocking effect is maintained after exposure.

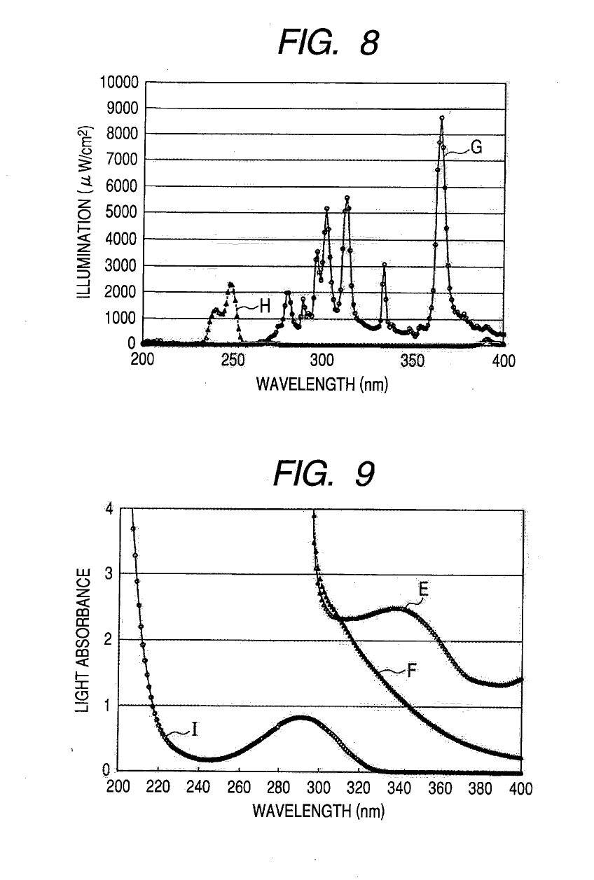

FIG. 8 is a graph illustrating exposure wavelength and luminance when an optical filter is used. Here, an example (H) in which an optical filter that blocks light with a wavelength of 260 nm or more is provided to an exposure apparatus for one-time exposure method, which includes a high-pressure mercury lamp, and an example (G) in which an optical filter that blocks light with a wavelength of 260 nm or less is provided are shown. FIG. 9 shows a spectrum I for polymethyl isopropenyl ketone together with the foregoing spectrums E and F. For example, when polymethyl isopropenyl ketone (PMIPK) is used as the first positive photosensitive resin layer 7 (see FIG. 9), it is preferable to perform exposure with the optical filter that blocks light with a wavelength of 260 nm or more provided. This is because the first positive photosensitive resin layer 7 absorbs light with a wavelength of 260 nm or more, and the first positive photosensitive resin layer 7 may be affected when the second positive photosensitive resin layer 8 is subjected to exposure. By means of the aforementioned technique, the second positive photosensitive resin layer 8 is exposed to light (FIG. 3B).

Development of the second positive photosensitive resin layer 8 (FIG. 3D) can be performed using, for example, a solvent that dissolves decomposed matter of the aforementioned copolymer (matter having a low molecular weight generated as a result of a main-chain decomposition reaction), and does not dissolve unreacted matter.

The removal of the mask 9′ formed of the first resist (FIG. 3C) is performed using a solvent that can dissolve or peel off the first resist. For example, a naphthoquinone-type positive photoresist functions as a positive resist in a proper exposure amount, and the exposed portion easily dissolves in an alkaline aqueous solution. However, it is known that in the case of a largely-excessive exposure amount, a cross-linking reaction occurs between molecules of the resin, which is a main component, and thus, hard to dissolve in an alkaline aqueous solution or a common organic solvent. In particular, a main chain decomposition-type positive resist exhibits relatively poor reaction efficiency, and thus, when a main chain decomposition-type positive resist with a large film thickness is used, it is necessary to apply a large amount of energy. Thus, a large amount of energy is applied also on the mask 9′ formed of the first resist, and a cross-linking reaction progresses in the first resist, which may result in difficulty to remove the mask 9′.

As a result of diligent study, the present inventors have discovered that it is particularly favorable to remove the mask resist using the following mixed solution:

A mixed solution containing at least:

a glycol ether with a carbon number of 6 or more, which can be mixed with water;

a nitrogenous basic organic solvent; and

water.

A glycol ether with a carbon number of 6 or more, which can be mixed with water, means a glycol ether that can be mixed with water at an arbitrary ratio. In particular, ethylene glycol monobutyl ether and/or diethylene glycol monobutyl ether can be used. For the nitrogenous basic organic solvent, in particular, ethanolamine and/or morpholine can be used.

This mixed solvent has both a dissolving ability as an organic solvent and a dissolving ability as an alkali aqueous solution. Accordingly, the mixed solvent is particularly suitable for dissolving, for example, a mask containing a naphthoquinone-type photoresist in which a cross-linking reaction has occurred. Also, this mixed solution can also function as a developer for the aforementioned copolymer that is suitable for use as the second positive resist. Accordingly, if the mixed solvent or a solvent having similar functions is used, development processing for the second positive photosensitive resin layer 8 and removal processing for the mask 9′ formed of the first resist can be performed simultaneously.

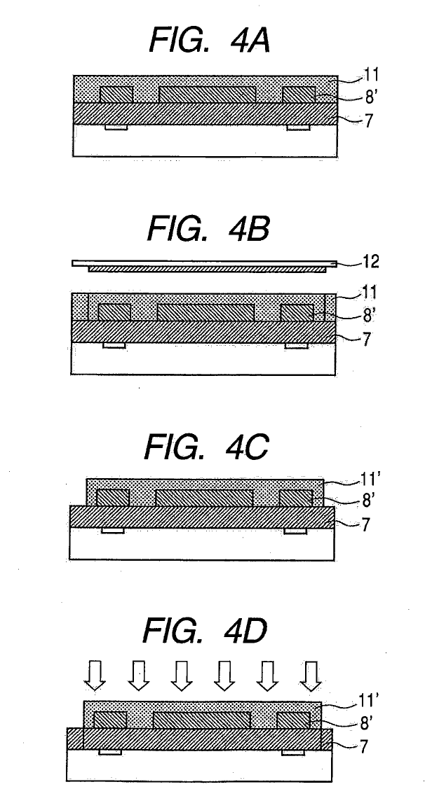

Next, as shown in FIG. 4A, a second resist 11 is deposited on the first positive photosensitive resin layer 7 on which an upper layer 8′ of a pattern in the shape of a flow path (template pattern that becomes a mold for forming the flow path) formed thereon. Then, as shown in FIG. 4B, patterned exposure is performed via a second reticle (mask) 12. Furthermore, as shown in FIG. 4C, development processing is performed, thereby forming a mask 11′ formed of the second resist 11 on the first positive photosensitive resin layer 7.

The second resist 11 is provided for forming a mask in an exposure process for patterning the first positive photosensitive resin layer 7 (FIG. 4D). Accordingly, the second resist 11 is required to have a light-blocking effect for the photosensitive wavelengths of the first positive photosensitive resin layer 7 (first wavelength range).

Also, the second resist 11 is formed by being coated over the surface with a difference in level caused by the template pattern upper layer 8′, which is formed of the second positive photosensitive resin, and thus, when coverage of the steps is considered, it is preferable to deposit a second resist 11 with a layer thickness larger than that of the first resist 9 layer. Furthermore, as with the first resist 9, the second resist 11 can be patterned by means of a stepper from the perspective of alignment accuracy, using an i-ray (365 nm), which is most widely used. More specifically, exposure can be performed using a reduced projection exposure apparatus that provides an i-ray. Examples of a suitable positive resist satisfying these requirements are similar to those that have already been described as examples of the first resist 9. Accordingly, the same type of resist can be used for the first resist 9 and the second resist 11.

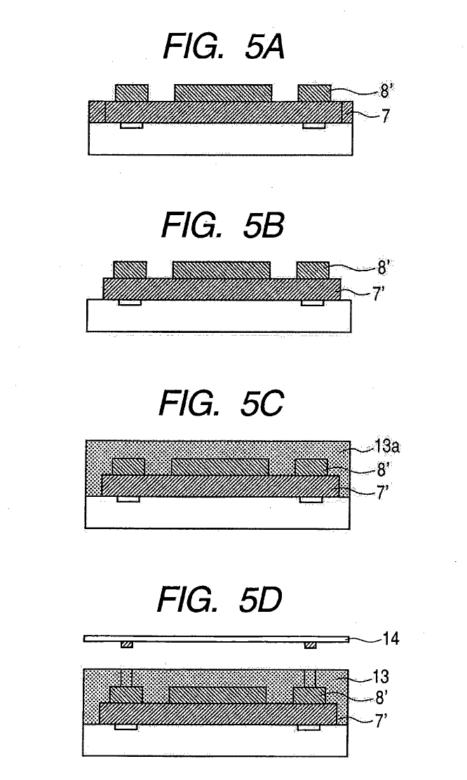

Next, as shown in FIG. 4D, exposure of the entire surface is performed using a photosensitive wavelength of the first positive photosensitive resin layer 7 via the mask 11′ formed of the second resist. Then, as shown in FIG. 5A, the mask 11′ formed of the second resist is removed. Furthermore, as shown in FIG. 5B, development of the first positive photosensitive resin layer 7 is performed, thereby forming a template pattern lower layer 7′, which is the other part of the template pattern for an ink flow path. The removal of the mask 11′ in FIG. 5A and development processing for the first positive photosensitive resin layer 7 in FIG. 5B can be performed simultaneously using the same solvent. Also, the development processing for the first positive photosensitive resin layer 7 in FIG. 5B can be performed before the removal of the mask 11′ in FIG. 5A.

FIG. 9 is a graph illustrating an example of the photosensitive wavelengths of the first positive photosensitive resin layer 7 and the light-blocking effect of the second resist 11. Here, polymethyl isopropenyl ketone (PMIPK) was used as the first positive photosensitive resin layer 7, and a product named OFPR-800 resist manufactured by Tokyo Ohka Kogyo Co., Ltd was used as the second resist 11. It can be seen from FIG. 9 that: the sensitive wavelengths of PMIPK are mainly in the range of around 260 to 320 nm (data for a film thickness of 15 μm); and light with the photosensitive wavelengths of PMIPK can be blocked by using OFPR-800 resist (data for a film thickness of 4 μm). Also, it can be seen that a sufficient light-blocking effect is maintained after exposure.

Accordingly, for the wavelength of light used for entire surface exposure via the mask 11′ (FIG. 4D), for example, light with a wavelength provided using an optical filter that blocks light with a wavelength of 260 nm or less can be used. Furthermore, the development of the first positive photosensitive resin layer 7 (FIG. 5B) and the removal of the mask 11′ (FIG. 5A) can be performed in a manner similar to the development of the second positive photosensitive resin layer 8 and the removal of the mask 9′, which have been described earlier.

After the process described above, the template patterns 7′ and 8′ for an ink flow path with a two-tier configuration, the alignment of which is controlled with high accuracy, can be prepared.

For the aforementioned resin layer and resist layer formation, a known coating method, such as spin coating, roll coating or slit coating, can be used. Also, such resin layers and resist layers can be formed by means of lamination using dry film positive resists. Furthermore, an additive, such as a light absorbent, may be added in the first and second positive photosensitive resins to prevent reflection from the substrate surface.

Next, as shown in FIG. 5C, the template patterns 7′ and 8′ for an ink flow path, which have been formed via the aforementioned process are coated by a coating resin 13a for forming ink flow path walls. Here, for example, the coating resin 13a may be applied by a method such as spin coating, roll coating or slit coating.

The coating resin 13a functions as an ink flow path forming member. Accordingly, a high mechanical strength as a structural material, adhesiveness to the underlying material, ink tolerance, and a resolution for providing a minute pattern of discharge ports are required. Examples of a suitable material satisfying these properties include a cationic polymerization-type epoxy resin composition containing an epoxy compound and a photocationic polymerization initiator.

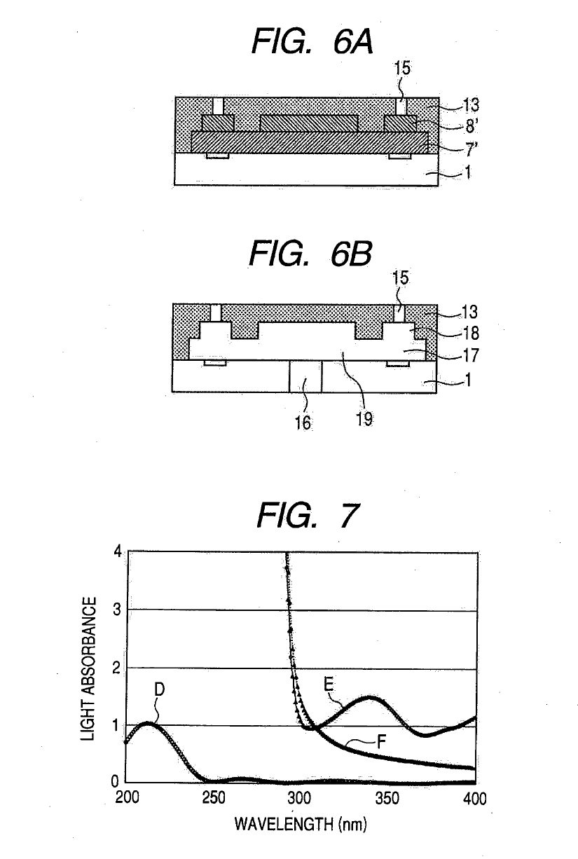

The subsequent process is performed in a similar manner as in the method described in embodiment 1 with reference to FIGS. 13A to 13C, thereby obtaining an ink jet head having a flow path 17 with a two-tier configuration as shown in FIGS. 6A and 6B. In FIG. 6B, the upper part and the lower part of the two-tier flow path 17 may be separately referred to as a flow path upper part 18 and a flow path lower part 19, respectively.

With the methods according to the present invention, which have been described in embodiments 1 to 3, the positional relationship among the discharge energy generating elements 2, and the ink flow path 17 and the discharge ports 15 can be controlled with high accuracy and good reproducibility, enabling stable manufacture of an ink jet head with favorable printing properties.

The present invention can also be applied to manufacture of an ink jet head having an ink flow path with a three or more-tier configuration. For example, when forming an ink flow path with a three-tier configuration, first, three positive photosensitive resin layers are formed, the aforementioned process of exposure via a resist mask and development is performed for the upper layer, the intermediate layer and the lower layer in this order, thereby forming an ink flow path with a three-tier configuration.

Examples of the present invention will be provided below. In the following description, “parts” means “mass parts”.

### Example 1

### Manufacture of an Ink Jet Head Having an Ink Flow Path with a Two-Tier Configuration-1

An ink jet head having an ink flow path with a two-tier configuration was manufactured according to the process illustrated in FIGS. 2A to 2E, FIGS. 3A to 3D, FIGS. 4A to 4D, FIGS. 5A to 5D and FIGS. 6A and 6B.

First, a substrate 1 with discharge energy generating elements 2 formed thereon was provided (FIG. 2A). In the present example, an 8-inch silicon substrate was used as the substrate 1, and thermoelectric conversion elements (heaters including material HfB₂) were used as the discharge energy generating element 2. Also, laminated layers of SiN and Ta were formed at the part of the substrate 1 on which a flow path is to be formed.

Next, a first positive photosensitive resin layer 7 was formed on the substrate 1 with the discharge energy generating elements 2 formed thereon (FIG. 2B). In the present example, as the first positive photosensitive resin, polymethyl isopropenyl ketone was provided by means of spin coating and baked at 150° C. for three minutes. The thickness of the resist layer 7 after the baking was 15 μm.

Subsequently, a second positive photosensitive resin layer 8 was further deposited on the first positive photosensitive resin layer 7 (FIG. 2C). In the present example, as the second positive photosensitive resin, a copolymer of methyl methacrylate and a methacrylic acid (relative proportion of monomers=90:10) was provided by means of spin coating to have a film thickness of 5 μm and baked at 150° C. for three minutes.

Furthermore, a first resist 9 was deposited on the second positive photosensitive resin layer 8 (FIG. 2D). In the present example, as the first resist 9, a naphthoquinone-type positive photoresist (product name: iP-5700 resist, manufactured by Tokyo Ohka Kogyo Co., Ltd.) was deposited to have a film thickness of 4 μm. Subsequently, using an i-ray stepper (product name: i5, manufactured by Canon Inc.), exposure was performed with an exposure amount of 200 J/m² via a first reticle 10 (FIG. 2E). Then, development processing was performed using 2.38 wt % of a tetramethyl ammonium hydroxide aqueous solution to perform patterning, thereby forming a mask 9′ formed of the first resist (FIG. 3A).

Next, exposure of the entire surface was performed using light with a photosensitive wavelength of the second positive photosensitive resin via the mask 9′(FIG. 3B). In the present example, using a deep-UV exposure apparatus including a filter that blocks light with a wavelength of 260 nm or more (product name: UX-3000, manufactured by Ushio, Inc.), exposure of the entire surface was performed with an exposure amount of 5000 mJ/cm².

Then, using a mixed solvent (A) with the following composition, removal of the mask 9′ and development of the second positive photosensitive resin layer 8 were performed simultaneously, thereby forming an upper layer 8′ of a template pattern for an ink flow path (FIGS. 3C and 3D).

Mixed Solvent (A):

60 vol % of diethylene glycol monobutyl ether;

5 vol % of ethanolamine;

20 vol % of morpholine; and

15 vol % of ion-exchanged water.

On the upper layer 8′, a naphthoquinone-type positive photoresist (product name: OFPR-800 resist, manufactured by Tokyo Ohka Kogyo Co., Ltd.) was deposited as a second resist so as to have a thickness of 4 μm (FIG. 4A). Subsequently, using an i-ray stepper (product name: i5), exposure was performed with an exposure amount of 800 J/m² via a second reticle (mask) 12 (FIG. 4B). Then, development processing was performed using 2.38 mass % of a tetramethyl ammonium hydroxide aqueous solution to perform patterning, thereby forming a mask 11′ formed of the second resist (FIG. 4C).

Next, exposure of the entire surface was performed using light with a photosensitive wavelength of the first positive photosensitive resin via the mask 11′ (FIG. 4D). In the present example, exposure of the entire surface was performed with an exposure amount of 10000 mJ/cm² using a deep-UV exposure apparatus (product name: UX-3000) including a filter that blocks light with a wavelength of 260 nm or less. Then, using the aforementioned mixed solvent (A), the mask 11′ was removed (FIG. 5A). Furthermore, the first positive photosensitive resin layer 7 was developed using methyl isobutyl ketone, thereby forming an lower layer 7′ of a template pattern for an ink flow path (FIG. 53). Consequently, template patterns 7′ and 8′ for an ink flow path with a two-tier configuration were obtained.

Next, a photosensitive resin composition (A) (coating resin 13a) with the following composition was provided on the template patterns 7′ and 8′ for an ink flow path by means of spin coating (film thickness of 15 μm on a flat plate), and prebaked at 90° C. for two minutes using a hot plate, thereby forming a layer of the coating resin 13a (FIG. 5C).

Photosensitive Resin Composition (A):

100 parts of an epoxy compound (product name: EHPE, manufactured by Daicel Chemical Industries, Ltd.);

5 parts of a polymerization initiator (product name: SP-172, manufactured by Adeka Corporation);

5 parts of an epoxy silane coupling agent (product name: A-187, manufactured by Nippon Unicar Co., Ltd.; and

100 parts of methyl isobutyl ketone.

Subsequently, a photosensitive resin composition (B) having the following composition is provided on the substrate that is being processed, by means of spin coating so as to have a film thickness of 1 μm and prebaked at 80° C. for three minutes (using a hot plate), thereby forming an ink repellent layer (not shown).

Photosensitive Resin Composition (B):

35 parts of an epoxy compound (product name: EHPE, manufactured by Daicel Chemical Industries, Ltd.);

25 parts of 2,2-bis(4-glycidyloxyphenyl)hexafluoropropane;

25 parts of 1,4-bis(2-hydroxyhexafluoroisopropyl)benzene;

16 parts of 3-(2-perfluorohexyl)ethoxy-1,2-epoxypropane;

4 parts of an epoxy silane coupling agent (product name: A-187, manufactured by Nippon Unicar Co., Ltd.);

5 parts of a polymerization initiator (product name: SP-172, manufactured by Adeka Corporation); and

100 parts of diethylene glycol monoethyl ether.

Next, using an i-ray stepper (product name: i5), patterned exposure was performed via a third reticle (mask) 14 with an exposure amount of 4000 J/m² (FIG. 5D). Then, PEB (post-exposure baking) was performed at 120° C. for 120 seconds using a hot plate. Subsequently, development processing was performed using methyl isobutyl ketone, rinse treatment was performed using isopropyl alcohol, and thermal treatment was performed at 100° C. for 60 minutes, thereby forming discharge ports 15 each having a diameter of 8 μm (FIG. 6A).

Next, using a deep-UV exposure apparatus (product name: UX-3000) with no optical filter provided, exposure of the entire surface was performed via the coating resin 13a with an exposure amount of 250000 mJ/cm², thereby solubilizing the template patterns 7′ and 8′ for an ink flow path. Subsequently, the substrate that is being processed was immersed in methyl lactate while being provided with ultrasound waves to dissolve and remove the template patterns 7′ and 8′, thereby forming an ink flow path 17 (FIG. 6B). In the present example, description of formation of an ink supply port 16 is omitted.

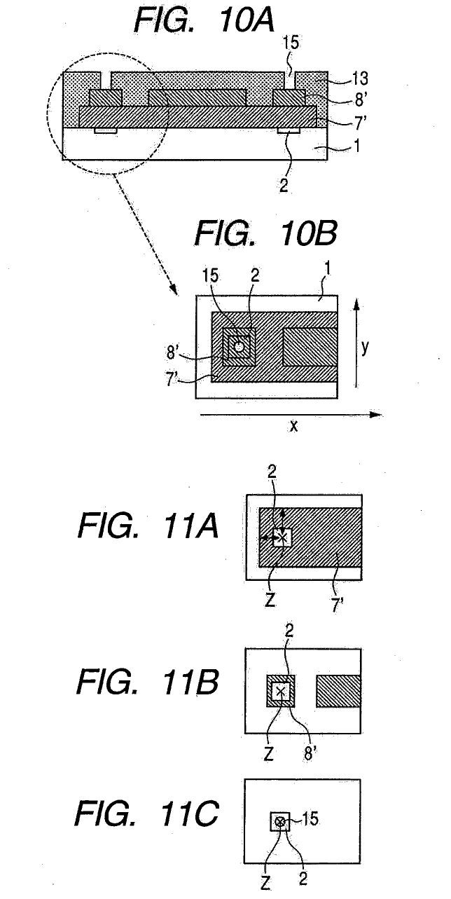

The simulated ink jet head manufactured as described above was observed using an optical microscope and an electron microscope to evaluate the positional relationship among the discharge energy generating elements 2, the lower layer 7′ and the upper layer 8′ of the template pattern, and the discharge ports 15. The position of the template pattern lower layer 7′ corresponds to the position of a first tier of the ink flow path, and the position of the template pattern upper layer 8′ corresponds to the position of a second tier of the ink flow path. FIGS. 10A and 10B are diagrams illustrating a method for measuring deviation amounts of the layers, and FIG. 11 are diagrams illustrating a position for measuring deviation amounts. As shown in FIGS. 10A and 10B, this evaluation was conducted by measuring the amounts of deviation of each part from the central position Z of a discharge energy generating element (heater) 2 in an x-direction and a y-direction. FIG. 11A illustrates measurement of the amounts of deviation of the position of the template pattern lower layer 7′ from the central position Z of a discharge energy generating element 2 (center of a heater) in the x-direction and the y-direction. FIG. 11B illustrate measurement of the amounts of deviation of the central position of the template pattern upper layer 8′ from the central position of the discharge energy generating element 2 (center of the heater) Z in the x-direction and the y-direction. FIG. 11C illustrates measurement of the amounts of deviation of the central position of a discharge port 15 from the central position Z of the discharge energy generating element 2 (center of the heater) in the x-direction and the y-direction. Table 1 indicates the results of the evaluation.

TABLE 1
Results of evaluation of deviation amounts in example 1

| | Amount of deviation from Z (μm) | | | |
|---|---|---|---|---|
| | | First-tier | Second-tier | |
| | Direction of | ink flow | ink flow | Discharge |
| | deviation | path | path | port |
| Central | x-direction | 0 | 0 | 0 |
| portion | y-direction | 0 | 0 | 0 |
| of the | | | | |
| substrate | | | | |
| Edge | x-direction | 0 | 0 | 0 |
| portion | y-direction | 0 | 0 | 0 |
| of the | | | | |
| substrate | | | | |

### Example 2

### Manufacture of an Ink Jet Head Having an Ink Flow Path with a Two-Tier Configuration-2

An ink jet head was manufactured according to the process illustrated in FIGS. 2A to 2E, FIGS. 3A to 3D, FIGS. 4A to 4D, FIGS. 5A to 5D and FIGS. 6A and 6B. In the present example, description will be given below only for the points that are different from example 1.

For formation of a first positive photosensitive resin layer 7, a copolymer of methyl methacrylate and a methacrylic acid (relative proportion of monomers=90:10) was used, and the thickness of the resist layer 7 was made to be 10 μm (FIG. 2B). For formation of a second positive photosensitive resin layer 8, polymethyl isopropenyl ketone was used, and the thickness was made to be 5 μm (FIG. 2C). For a first resist 9, a naphthoquinone-type positive photoresist (product name: OFPR-800 resist) was used, and the film thickness was made to be 2 μm (FIG. 2D). Exposure was performed via a first reticle 10 with an exposure amount of 500 J/m² using an i-ray stepper (FIG. 2E).

Using a filter that blocks light with a wavelength of 260 nm or less as a filter for a process of exposure via a mask 9′ formed of the first resist, exposure was performed with an exposure amount of 6000 mJ/cm² (FIG. 3B). Then, first, the second positive photosensitive resin layer 8 was developed using methyl isobutyl ketone (FIG. 3D), and subsequently, the mask 9′ was removed using a mixed solvent (A), which is the same as one used in example 1 (FIG. 3C).

For the second resist 11, a naphthoquinone-type positive photoresist (product name: iP-5700 resist) was used, and the film thickness was made to be 5 μm (FIG. 4A). Exposure was performed via a second reticle 12 using an i-ray stepper with an exposure amount of 300 J/m² (FIG. 4B).

Using a filter that blocks light with a wavelength of 260 nm or more as a filter for a process of exposure via a mask 11′ formed of the second resist, exposure was performed with an exposure amount of 8000 mJ/cm² (FIG. 4D). Then, using the mixed solvent (A), which is the same as one used in example 1, removal of the mask 11′ and development of the first positive photosensitive resin layer 7 were performed simultaneously (FIGS. 5A and 5B).

Subsequently, a simulated ink jet head was manufactured according to the process similar to that in example 1 (FIGS. 5C, 5D, 6A and 6B), and an evaluation was made in a manner similar to that of example 1. Table 2 indicates the results of the evaluation.

TABLE 2
Results of evaluation of deviation amounts in example 2

| | Amount of deviation from Z (μm) | | | |
|---|---|---|---|---|
| | | First-tier | Second-tier | |
| | Direction of | ink flow | ink flow | Discharge |
| | deviation | path | path | port |
| Central | x-direction | 0 | 0 | 0 |
| portion | y-direction | 0 | 0 | 0 |
| of the | | | | |
| substrate | | | | |
| Edge | x-direction | 0 | 0 | 0 |
| portion | y-direction | 0 | 0 | 0 |
| of the | | | | |
| substrate | | | | |

### Example 3

### Manufacture of an Ink Jet Head Having an Ink Flow Path with a Two-Tier Configuration-3

An ink jet head was manufactured according to the process illustrated in FIGS. 2A to 2E, FIGS. 3A to 3D, FIGS. 4A to 4D, FIGS. 5A to 5D and FIGS. 6A and 6B. In the present example, description will be given below only for the points that are different from example 1.

For a first resist 9, a naphthoquinone-type positive photoresist (product name: OFPR-800 resist) was used and the film thickness was made to be 2 μm (FIG. 2D). Exposure was performed via a first reticle 10 with an exposure amount of 500 J/m² using an i-ray stepper (FIG. 2E).

The film thickness of a naphthoquinone-type positive photoresist (product name: OFPR-800 resist), which is a second resist 11, was made to be 6 μm (FIG. 4A).

Subsequently, a simulated ink jet head was manufactured according to the process similar to that in example 1 (FIGS. 4B, 4C and 4D, FIGS. 5A to 5D and FIGS. 6A and 6B) and evaluated. Table 3 indicates the results of the evaluation.

TABLE 3
Results of evaluation of deviation amounts in example 3

| | Amount of deviation from Z (μm) | | | |
|---|---|---|---|---|
| | | First-tier | Second-tier | |
| | Direction of | ink flow | ink flow | Discharge |
| | deviation | path | path | port |
| Central | x-direction | 0 | 0 | 0 |
| portion | y-direction | 0 | 0 | 0 |
| of the | | | | |
| substrate | | | | |
| Edge | x-direction | 0 | 0 | 0 |
| portion | y-direction | 0 | 0 | 0 |
| of the | | | | |
| substrate | | | | |

### Example 4

### Manufacture of an Ink Jet Head Having an Ink Flow Path with a Single-Tier Configuration-1

An ink jet head having an ink flow path with a single-tier configuration was manufactured according to the following process.

First, a substrate 1 with discharge energy generating elements 2 formed thereon, which is the same as one used in example 1, was provided (FIG. 2A). Next, a first positive photosensitive resin layer 7 was formed on this substrate 1 (FIG. 2B). In the present example, as the first positive photosensitive resin, a copolymer of methyl methacrylate and a methacrylic acid (relative proportions of monomers=90:10) was used, and the thickness of the resist layer 7 was made to be 10 μm.

Next, the process related to a second positive photosensitive resin layer 8 and a first resist 9 were omitted, and a second resist 11 was deposited directly on the first positive photosensitive resin layer 7. In the present example, as the second resist 11, a naphthoquinone-type positive photoresist (product name: iP-5700 resist) was used and deposited so as to have a film thickness of 5 μm. Subsequently, using an i-ray stepper (product name: i5), exposure was performed via a second reticle 12 with an exposure amount of 300 J/m². Then, development processing was performed using 2.38 mass % of a tetramethyl ammonium hydroxide aqueous solution to perform patterning, thereby forming a mask 11′ formed of the second resist.

Next, exposure of the entire surface was performed via the mask 11′ using light with a photosensitive wavelength of the first positive photosensitive resin. In the present example, using a deep-UV exposure apparatus (product name: UX-3000) with no optical filter provided, exposure of the entire surface was performed with an exposure amount of 8000 mJ/cm². Then, using a mixed solvent (A), which is the same as one used in example 1, removal of the mask 11′ and development of the first positive photosensitive resin layer 7 were performed simultaneously. Consequently, a template pattern 7′ for an ink flow path with a single-tier configuration was obtained.

Subsequently, a simulated ink jet head was manufactured according to process similar to that in example 1 (FIGS. 5C, 5D, 6A and 6B) and evaluated. Table 4 indicates the results of the evaluation.

TABLE 4
Results of evaluation of deviation amounts in example 4

| | Amount of deviation from Z (μm) | | |
|---|---|---|---|
| | Direction of | First-tier ink | |
| | deviation | flow path | Discharge port |
| Central | x-direction | 0 | 0 |
| portion of | y-direction | 0 | 0 |
| the substrate | | | |
| Edge portion | x-direction | 0 | 0 |
| of the | y-direction | 0 | 0 |
| substrate | | | |

### Example 5

### Manufacture of an Ink Jet Head Having an Ink Flow Path with a Single-Tier Configuration-2

An ink jet head was manufactured according to the following process. In the present example, description will be given below only for the points different from example 4.

For formation of a first positive photosensitive resin layer 7, polymethyl isopropenyl ketone was used, and the thickness of the resist layer 7 was made to be 15 μm. For a second resist 11, a naphthoquinone-type positive photoresist (product name: OFPR-800 resist) was used, and the film thickness was made to be 3 μm. Exposure was performed via a second reticle 12 with an exposure amount of 500 J/m² using an i-ray stepper.

For removal of a mask 11′ and development of the first positive photosensitive resin layer 7, first, the mask 11′ was removed using a mixed solvent (A), and then, the first positive photosensitive resin layer 7 was developed using methyl isobutyl ketone. Consequently, a template pattern 7′ for an ink flow path with a single-tier configuration was obtained.

Subsequently, a simulated ink jet head was manufactured according to process similar to that in example 1 (FIGS. 5C, 5D, 6A and 6B) and evaluated. Table 5 indicates the results of evaluation.

TABLE 5
Results of evaluation of deviation amounts in example 5

| | Amount of deviation from Z (μm) | | |
|---|---|---|---|
| | Direction of | First-tier ink | |
| | deviation | flow path | Discharge port |
| Central | x-direction | 0 | 0 |
| portion of | y-direction | 0 | 0 |
| the substrate | | | |
| Edge portion | x-direction | 0 | 0 |
| of the | y-direction | 0 | 0 |
| substrate | | | |

### Comparative Example 1

First, the same process as in example 1 was taken until formation of a first positive photosensitive resin layer and a second positive photosensitive resin layer (FIGS. 2A, 2B and 2C). In the present comparative example, as illustrated in FIG. 18, a first positive photosensitive resin layer 3 and a second positive photosensitive resin layer 4 are provided on a substrate.

Next, using a deep-UV exposure apparatus (product name: UX-3000) including a filter that blocks light with a wavelength of 260 nm or more, patterned exposure was performed via a second mask 5 with an exposure amount of 5000 mJ/cm² (FIG. 18A). Next, using a mixed solvent (A), which is the same as one used in example 1, the second positive photosensitive resin layer (second positive photosensitive material layer 4) was developed, thereby forming the upper layer 4′ of a template pattern for an ink flow path (FIG. 18B).

Next, using a deep-UV exposure apparatus (product name: UX-3000) including a filter that blocks light with a wavelength of 260 nm or less, patterned exposure was performed via a first mask 6 with an exposure amount of 10000 mJ/cm² (FIG. 18C). Next, using methyl isobutyl ketone, the first positive photosensitive resin layer (first positive photosensitive material layer 3) was developed, thereby forming the upper layer 3′ for the template pattern for an ink flow path (FIG. 18D). Consequently, template patterns 3′ and 4′ for an ink flow path with a two-tier configuration were obtained.

Subsequently, a simulated ink jet head was manufactured according to process similar to that in example 1 (FIGS. 5C, 5D, 6A and 6B) and evaluated in a manner similar to that of example 1. Table 6 indicates the results of the evaluation.

TABLE 6
Results of evaluation of deviation amounts in comparative
example 1

| | Amount of deviation from Z (μm) | | | |
|---|---|---|---|---|
| | | First-tier | Second-tier | |
| | Direction of | ink flow | ink flow | Discharge |
| | deviation | path | path | port |
| Central | x-direction | +1 | +2 | 0 |
| portion | y-direction | −1 | +1 | 0 |
| of the | | | | |
| substrate | | | | |
| Edge | x-direction | +3 | +4 | 0 |
| portion | y-direction | −3 | +3 | 0 |
| of the | | | | |
| substrate | | | | |

### Example 6

First, a silicon substrate 1 provided with heaters 2 (material: TaSiN) as energy generating elements, and also with laminated layers of SiN and Ta (not illustrated) on a liquid flow path forming area, was provided (FIG. 12A).

Next, polymethyl isopropenyl ketone is provided on the substrate by means of spin coating and baked at 120° C. for six minutes, thereby being formed as a first layer 22. The film thickness of the resist layer after the baking was 15 μm.

Subsequently, for forming a resist mask, a composition containing an iP-5700 resist (manufactured by Tokyo Ohka Kogyo Co., Ltd.) and 2-hydroxy-4-octoxybenzophenone (manufactured by Sankyo Chemical Co., Ltd.) was deposited so as to have a film thickness of 4 μm, thereby forming a second layer 23 (FIG. 12C).

Subsequently, using an i-ray stepper (i5, manufactured by Canon, Inc.), exposure of the second layer was performed via a mask with an exposure amount of 8000 J/m² (FIG. 12D).

Next, development was performed using 2.38 wt % of a tetramethyl ammonium hydroxide aqueous solution, thereby forming a resist pattern 24 (FIG. 12E).

Next, using the resist pattern 24 as a mask, exposure of the entire surface was performed using a deep-UV exposure apparatus (UX-3000, manufactured by Ushio, Inc.) with an exposure amount of 14000 J/cm² (FIG. 12F). Subsequently, the resist pattern 24 was removed using a mixed solvent with the following composition:

60 vol % of diethylene glycol monobutyl ether;

5 vol % of ethanolamine;

20 vol % of morpholine; and

15 vol % of ion-exchanged water.

Next, the first layer 22 was developed using methyl isobutyl ketone, thereby forming an ink flow path pattern 25 (FIG. 12H).

Next, a photosensitive resin composition having the following composition was provided by means of spin coating (film thickness on a flat plate: 15 μm), and prebaked at 90° C. for two minutes (using a hot plate), thereby forming a coating resin layer 13a (FIG. 13A).

100 weight parts of EHPE (manufactured by Daicel Chemical Industries, Ltd.);

5 weight parts of SP-172 (manufactured by Adeka Corporation);

5 weight parts of A-187 (manufactured by Dow Corning Toray Co., Ltd.); and

100 weight parts of methyl isobutyl ketone.

Subsequently, a photosensitive resin composition having the following composition is applied to the substrate that is being processed, by means of spin coating so as to have a film thickness of 1 μm and prebaked at 80° C. for three minutes (using a hot plate), thereby forming an ink repellent layer (not shown).

35 weight parts of EHPE (manufactured by Daicel Chemical Industries, Ltd.);

25 weight parts of 2,2-bis(4-glycidyloxyphenyl)hexafluoropropane;

25 weight parts of 1,4-bis(2-hydroxyhexafluoroisopropyl)benzene;

16 weight parts of 3-(2-perfluorohexyl)ethoxy-1,2-epoxypropane;

4 weight parts of A-187 (manufactured by Dow Corning Toray Co., Ltd.);

5 weight parts of SP-172 (manufactured by Adeka Corporation); and

100 weight parts of diethylene glycol monoethyl ether.

Next, after patterned exposure was performed with an exposure amount of 4000 J/m² using an i-ray stepper (i5, manufactured by Canon Inc.), PEB was performed at 90° C. for 240 seconds using a hot plate. Subsequently, development was performed using methyl isobutyl ketone, rinse treatment was performed using isopropyl alcohol, and thermal treatment was performed at 140° C. for 60 minutes, thereby forming ink discharge ports 15 (FIG. 13B). In the present example, a pattern of discharge ports each having a diameter of 8 μm was formed.

Next, using a deep-UV exposure apparatus (UX-3000, manufactured by Ushio, Inc.), exposure of the entire surface was performed via the coating resin with an exposure amount of 250000 mJ/cm², thereby solubilizing an ink flow path pattern. Subsequently, the substrate that is being processed was immersed in methyl lactate while being provided with ultrasound waves to dissolve and remove the flow path pattern, thereby forming a flow path 17 (FIG. 13C).

Description of formation of an ink supply port 9 (not shown) is omitted.

### Experimental Example

Liquid discharge heads with different film thicknesses of a resist pattern and different kinds of a benzophenone compound were manufactured based on the above-described example and the angle between the flow path walls and the substrate was evaluated. The rest of the points was the same as in the above-described example.

Table 7 indicates the results, and the evaluation criteria were indicated below.

TABLE 7

| | Film thickness of | | |
|---|---|---|---|
| | resist pattern (μm) | | |
| (Benzophenone compound) | 6 | 5 | 4 |
| 2-hydroxy-4-octoxybenzophenone (manufactured | B | A | A |
| by Sankyo Chemical Co., Ltd.) | | | |
| 2-hydroxy-4-methoxybenzophenone | C | B | B |
| (manufactured by Sankyo Chemical Co., Ltd) | | | |
| 2,4-dihydroxybenzophenone (manufactured by | C | B | B |
| Sankyo Chemical Co., Ltd) | | | |
| 2,3,4-trihydroxybenzophenone (manufactured | C | C | B |
| by Iwate Chemical Corporation) | | | |
| 2,3,4,4′-tetrahydroxybenzophenone | C | C | B |
| (manufactured by Iwate Chemical Corporation) | | | |
| 2,3′,3,4′-tetrahydroxybenzophenone | C | C | B |
| (manufactured by Tokyo Chemical Industry, | | | |
| Co., Ltd.) | | | |

### <Evaluation Criteria>

Perpendicularity of the flow path walls was evaluated with θ (the angle formed between the flow path walls and the substrate surface) illustrated in FIG. 13.

### A: θ is 90°

B: θ is less than 90°: around 85°
C: θ is less than 85°, but at a level that causes no problem in use as a head, considering from the area of contact between the substrate and the flow path forming member.

Also, for the liquid discharge heads manufactured in the above-described experimental example, no damage, such as deformation, was found in the first positive photosensitive resin in exposure for forming a flow path pattern 25. This can be considered to resulting from sufficient light-blocking effect of a resist pattern 24.

### Example 7

An ink jet head was manufactured according to the process illustrated in FIGS. 15A to 15D. First, a substrate 1 was provided as illustrated in FIG. 15A. The substrate was provided with energy generating elements 2.

Next, as shown in FIG. 15B, polymethyl isopropenyl ketone is provided on the substrate 1 by means of spin coating as a first positive resist 22 and baked at 150° C. for three minutes. The film thickness of the resist layer after the baking was 14

Next, as illustrated in FIG. 15C, a resin composition having the following composition is provided by means of spin coating as a resin composition 26 having a light-blocking effect for light in the photosensitive wavelength range of the first positive resist 22, and baked at 120° C. for three minutes. The film thickness of the resin composition layer after the baking was 1.5 μm.

50 weight parts of a cresol novolac resin

30 weight parts of a carbon black dispersion liquid (3-methoxybutyl acetate solvent with an average particle diameter of 100 nm and containing 20 wt % of carbon black); and

70 weight parts of propylene glycol monomethyl ether acetate.

Subsequently, as illustrated in FIG. 15D, an iP-5700 resist, manufactured by Tokyo Ohka Kogyo Co., Ltd., was deposited as a resist 23 so as to have a film thickness of 3 μm. Subsequently, using an i-ray stepper (i5, manufactured by Canon Inc.), exposure was performed via a first reticle 27 with an exposure amount of 200 J/m² (FIG. 16A), and development was performed using 2.38 wt % of a tetramethyl ammonium hydroxide aqueous solution. At this time, etching of the resin composition 26 was performed simultaneously (FIG. 16C).

Next, using a resist mask 24 and a pattern 28 as masks, exposure of the entire surface was performed with an exposure amount of 8000 mJ/cm² using a deep-UV exposure apparatus (UX-3200, manufactured by Ushio, Inc.) (FIG. 16E).

Subsequently, the resist mask 24 and the pattern 28 were removed while developing the positive photosensitive resin 22 using methyl isobutyl ketone, thereby forming an ink flow path pattern 25 (FIG. 16G).

Next, a photosensitive resin composition having the following composition was provided by means of spin coating (film thickness on a flat plate of 11 μm), and prebaked at 90° C. for two minutes (using a hot plate), thereby forming a layer coating the flow path pattern 25 (not illustrated).

100 weight parts of EHPE (manufactured by Daicel Chemical Industries, Ltd.);

5 weight parts of SP-172 (manufactured by Adeka Corporation);

5 weight parts of A-187 (manufactured by Nippon Unicar Co., Ltd.); and

100 weight parts of methyl isobutyl ketone.

Subsequently, a photosensitive resin composition having the following composition was applied to the substrate that is being processed, by means of spin coating so as to have a film thickness of 1 μm, and prebaked at 80° C. for three minutes (using a hot plate), thereby forming an ink repellent layer (not illustrated).

35 weight parts of EHPE (manufactured by Daicel Chemical Industries, Ltd.);

25 weight parts of 2,2-bis(4-glycidyloxyphenyl)hexafluoropropane;

25 weight parts of 1,4-bis(2-hydroxyhexafluoroisopropyl)benzene;

16 weight parts of 3-(2-perfluorohexyl)ethoxy-1,2-epoxypropan;

4 weight parts of A-187 (manufactured by Nippon Unicar Co., Ltd.);

5 weight parts of SP-172 (manufactured by Adeka Corporation); and

100 weight parts of diethylene glycol monoethyl ether.

Next, after patterned exposure was performed with an exposure amount of 4000 J/m² using an i-ray stepper (i5, manufactured by Canon Inc.), the ink repellant layer was baked at 120° C. for 120 seconds using a hot plate. Development was performed using methyl isobutyl ketone, rinse treatment was performed using isopropyl alcohol, and thermal treatment was performed at 100° C. for 60 minutes, thereby forming ink discharge ports 15. In the present example, a pattern of discharge ports each having diameter of 13 μm was formed.

Next, using a deep-UV exposure apparatus (UX-3200, manufactured by Ushio, Inc.), exposure of the entire surface was performed via the coating resin with an exposure amount of 250000 mJ/cm², thereby solubilizing an ink flow path pattern 25. Subsequently, the substrate that is being processed was immersed in methyl lactate while being provided with ultrasound waves to dissolve and remove the ink flow path pattern, thereby forming an flow path 17 (FIG. 16H).

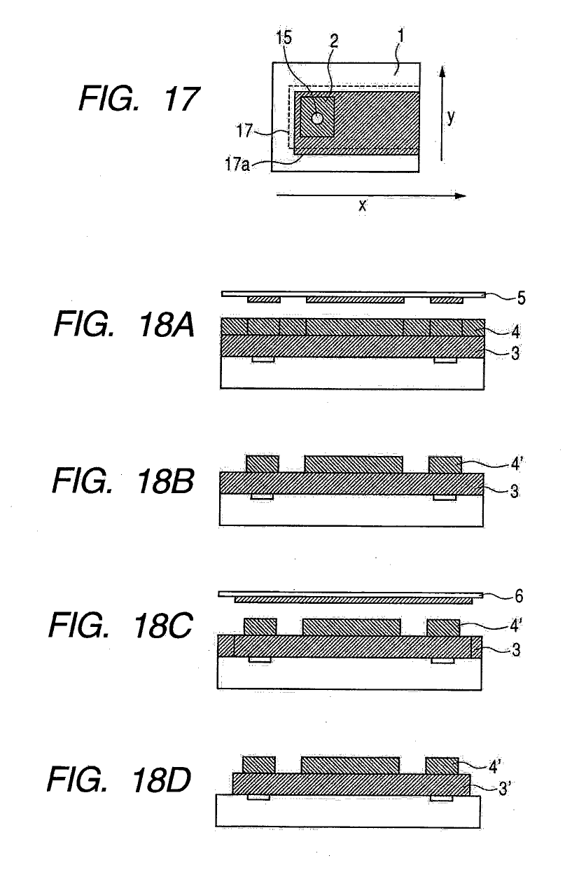

The simulated ink jet head manufactured as described above was observed using an optical microscope and an electron microscope to evaluate the positional relationship among energy generating elements, the ink flow path and the discharge ports. The evaluation was made by measuring the amounts of deviation from the intended ink flow path position in x- and y-directions. FIG. 17 illustrates a method for measuring the amounts of deviation. FIG. 17 shows the amount of deviation x in a direction along the flow path, the amount of deviation y in a direction perpendicular to x, a discharge port 15, an energy generating element 2, the position of the flow path 17 when the amounts of deviation are 0, and the position of the flow path 17a when deviation has occurred.

### Comparative Example 2

Polymethyl isopropenyl ketone was used as the positive photosensitive resin layer 22 illustrated in FIG. 15B, and in the exposure process illustrated in FIG. 16E, patterned exposure was performed using a UV exposure apparatus (UX-3200, manufactured by Ushio, Inc.), without using a resist mask 24 and another pattern mask 28.

Subsequently, development processing was performed to form a pattern for an ink flow path. For the subsequent process, the same process as in example 7 was employed, thereby manufacturing an ink jet head.

Table 8 indicates the results of evaluation of both example 7 and comparative example 2.

TABLE 8

| Measurement | Amount of deviation from the intended ink flow path | | | |
|---|---|---|---|---|
| position | position (μm) | | | |
| (8-inch | Example 1 | | Comparative example | |
| wafer) | x-direction | y-direction | x-direction | y-direction |
| Upper edge | 0 | 0 | +2 | −1 |
| Left edge | 0 | 0 | +3 | −2 |
| Center | 0 | 0 | +1 | −1 |
| Right edge | 0 | 0 | +3 | −2 |
| Lower edge | 0 | 0 | +2 | −1 |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-327473, filed Dec. 19, 2007, and Japanese Patent Application No. 2008-278427, filed Oct. 29, 2008 which are hereby incorporated by reference herein their entirety.

1. A method for manufacturing a liquid discharge head including a flow path forming member for forming a flow path communicably connected to a discharge port that discharges a liquid on or above a substrate, the method comprising:
providing a layer containing a photosensitive resin on or above the substrate;
providing a mask layer that enables reduction of transmission of light with a photosensitive wavelength of the photosensitive resin, at an area on the layer containing the photosensitive resin, the area corresponding to the flow path;
performing exposure for the layer containing the photosensitive resin using the mask layer as a mask to make the layer containing the photosensitive resin be a pattern having the shape of the flow path;
providing a layer that becomes the flow path forming member, so as to cover the pattern;
forming the discharge port at a part of the layer that becomes the flow path forming member; and
forming the flow path by removing the pattern.

2. The method according to claim 1, wherein
the photosensitive resin is a positive photosensitive resin.

3. The method according to claim 1, wherein the providing a mask layer further comprising:
providing a layer containing a naphthoquinone diazide derivative and a hydroxybenzophenone compound, for forming the mask layer, on the photosensitive resin; and
performing patterning, which includes exposure, for the layer containing a naphthoquinone diazide derivative and a hydroxybenzophenone compound, thereby forming the mask layer.

4. The method according to claim 1, wherein after the exposure, the mask layer is removed together with a part of the photosensitive resin subjected to the exposure.

5. The method according to claim 1, wherein the mask layer includes two layers.

6. The method according to claim 3, wherein the hydroxybenzophenone compound is 2-hydroxy-4-octoxybenzophenone.

7. The method according to claim 3, wherein exposure is performed for the layer containing a naphthoquinone diazide derivative and a hydroxybenzophenone compound using an i ray.

8. The method according to claim 1, wherein the providing a mask layer that enables reduction of transmission of light with a photosensitive wavelength of the photosensitive resin, at an area on the layer containing the photosensitive resin, the area corresponding to the flow path, includes:
providing a first layer containing a photosensitive resin, and a second layer provided on the first layer, the second layer containing a photosensitive resin, on or above the substrate; and
providing the mask layer on the second layer.

9. The method according to claim 1, wherein the providing a mask layer that enables reduction of transmission of light with a photosensitive wavelength of the photosensitive resin, at an area on the layer containing the photosensitive resin, the area corresponding to the flow path, includes:
providing a first layer containing a photosensitive resin, and a pattern provided on the first layer, the pattern having the shape of a part of the flow path, on or above the substrate; and
providing the mask layer so as to cover the pattern having the shape of a part of the flow path and the first layer.
